(19) United States
(12) Patent Application Publication
(10) Pub. No.: US 2022/0123714 A1
(43) Pub. Date: Apr. 21, 2022

(54) BULK ACOUSTIC WAVE RESONATOR

(71) Applicant: SAMSUNG ELECTRO-MECHANICS CO., LTD., Suwon-si (KR)

(72) Inventors: Dae Hun JEONG, Suwon-si (KR); Jeong Hoon RYOU, Suwon-si (KR); Jong Woon KIM, Suwon-si (KR)

(73) Assignee: SAMSUNG ELECTRO-MECHANICS CO., LTD., Suwon-si (KR)

(21) Appl. No.: 17/232,828

(22) Filed: Apr. 16, 2021

(30) Foreign Application Priority Data
Oct. 16, 2020 (KR) 10-2020-0134449

(51) Int. Cl. H03H 9/08; H03H 9/17

(52) U.S. Cl. CPC H03H 9/08; H03H 9/173

(57) ABSTRACT

A bulk acoustic wave resonator includes: a substrate; a resonant portion including a sequentially stacked first electrode, piezoelectric layer, and second electrode; a cavity defined between the substrate and the resonant portion; and a heat dissipation portion disposed in the cavity and supporting the resonant portion. The second electrode includes a first region and a second region having a thickness greater than a thickness of the first region, and the second region is disposed above the heat dissipation portion.

### CROSS-REFERENCE TO RELATED APPLICATION(S)

This application claims the benefit under 35 USC 119(a) of Korean Patent Application No. 10-2020-0134449 filed on Oct. 16, 2020 in the Korean Intellectual Property Office, the entire disclosure of which is incorporated herein by reference for all purposes.

### BACKGROUND

### 1. Field

The following description relates to a bulk acoustic wave resonator.

### 2. Description of Background

In accordance with the trend toward miniaturization of a wireless communications device, miniaturization of high frequency component technology has been actively demanded. As an example, there is a bulk acoustic wave (BAW) resonator type filter using semiconductor thin film wafer manufacturing technology.

A bulk acoustic wave (BAW) resonator refers to a thin film type element generating resonance using piezoelectric characteristics of a piezoelectric dielectric material deposited on a silicon wafer, a semiconductor substrate, and implemented as a filter.

An interest in 5G communications technology has increased, and technology development of a bulk acoustic wave resonator that may be implemented in a candidate band has actively been conducted.

However, in a case of 5G communications using a sub-6 GHz (4 to 6 GHz) frequency band, a bandwidth increases and a communication distance is shortened, such a signal strength or power of the bulk acoustic wave resonator may increase.

When the power of the bulk acoustic wave resonator increases, a temperature of a resonant portion tends to increase linearly. When the temperature of the resonant portion increases as described above, there may be a problem in which a frequency is changed or the bulk acoustic wave resonator is damaged due to heat.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

A bulk acoustic wave resonator in which damage to a resonant portion due to heat may be prevented.

In one general aspect, a bulk acoustic wave resonator includes: a substrate; a resonant portion including a sequentially stacked first electrode, piezoelectric layer, and second electrode; a cavity defined between the substrate and the resonant portion; and a heat dissipation portion disposed in the cavity and supporting the resonant portion, wherein the second electrode includes a first region and a second region having a thickness greater than a thickness of the first region, and the second region is disposed above the heat dissipation portion.

The second electrode may include an inclined surface at a boundary between the first region and the second region.

The heat dissipation portion may be bonded to the resonant portion and the second region of the second electrode may have an area greater than an area of a bonded surface of the heat dissipation portion bonded to the resonant portion, and the heat dissipation portion may be disposed so that an entirety of the bonded surface faces the second region of the second electrode.

The heat dissipation portion may include a heat conduction portion having a pillar shape in which one end is bonded to the resonant portion and the other end is bonded to the substrate.

The heat dissipation portion may include an etch-stop layer surrounding a side surface of the heat conduction portion.

The heat conduction portion may include a material having thermal conductivity higher than a thermal conductivity of the etch-stop layer.

A boundary between the first region of the second electrode and the second region of the second electrode may be spaced apart from a side surface of the heat dissipation portion by a predetermined distance in a surface direction of the resonant portion.

A horizontal distance from the side surface of the heat dissipation portion to the boundary between the first region of the second electrode and the second region of the second electrode may be λ/4 or an integer multiple of λ/4 in which λ is a wavelength of a lateral wave propagated from the resonant portion to the heat dissipation portion.

The second electrode may include a vertical surface or a stepped surface at a boundary between the first region and the second region.

The second region of the second electrode may have an annular ring shape along a contour of the heat dissipation portion.

The bulk acoustic wave resonator may include an insertion layer disposed between the first electrode and the piezoelectric layer, and at least a portion of the piezoelectric layer may be raised by the insertion layer.

The insertion layer may include an inclined surface, the piezoelectric layer may include a piezoelectric portion disposed on the first electrode and an inclined portion disposed on the inclined surface of the insertion layer, and in a cross section of the resonant portion, a distal end of the second electrode may be disposed on the inclined portion of the piezoelectric layer.

The piezoelectric layer may include an extending portion disposed outside the inclined portion, and at least a portion of the second electrode may be disposed on the extending portion of the piezoelectric layer.

The second region of the second electrode may have a thickness greater than a thickness of the insertion layer.

In another general aspect, a bulk acoustic wave resonator includes: a substrate; a resonant portion including a sequentially stacked first electrode, a piezoelectric layer, and a second electrode; a cavity defined between the substrate and the resonant portion; and a heat dissipation portion disposed in the cavity and supporting the resonant portion, wherein the second electrode includes an electrode layer stacked on the piezoelectric layer and a thickened layer partially formed on a region of the electrode layer corresponding to the heat dissipation portion to increase a thickness of the second electrode, and the thickened layer has an area greater than an area of a bonded surface of the heat dissipation portion bonded to the resonant portion.

An entirety of a side surface of the thickened layer may be disposed above the cavity.

In another general aspect, a bulk acoustic wave resonator includes: a substrate; a resonant portion including a first electrode, a piezoelectric layer disposed on the first electrode, and a second electrode disposed on the piezoelectric layer and including a thickened portion; a cavity defined between the substrate and the resonant portion; and a heat dissipation pillar disposed in the cavity and bonded to the resonant portion such that at least a portion of the thickened portion of the second electrode overlaps the heat dissipation pillar in a thickness direction of the bulk acoustic wave resonator.

The thickened portion of the second electrode may have a length along a direction normal to the thickness direction of the bulk acoustic wave resonator that is greater than a length of a surface of the heat dissipation pillar that is bonded to the resonant portion along the direction normal to the thickness direction of the bulk acoustic wave resonator.

Other features and aspects will be apparent from the following detailed description, the drawings, and the claims.

### BRIEF DESCRIPTION OF DRAWINGS

FIG. 1 is a plan view of a bulk acoustic wave resonator according to an example.

FIG. 2 is a cross-sectional view taken along line I-I′ of FIG. 1.

FIG. 3 is a cross-sectional view taken along line II-II′ of FIG. 1.

FIG. 4 is a cross-sectional view taken along line III-III′ of FIG. 1.

FIGS. 5 and 6 are enlarged views of part A of FIG. 2.

FIGS. 7, 8, 9, 10, and 11 are schematic cross-sectional views illustrating bulk acoustic wave resonators according to other examples.

Throughout the drawings and the detailed description, the same reference numerals refer to the same elements. The drawings may not be to scale, and the relative size, proportions, and depictions of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that would be well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will fully convey the scope of the disclosure to one of ordinary skill in the art.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The drawings may not be to scale, and the relative sizes, proportions, and depiction of elements in the drawings may be exaggerated for clarity, illustration, and convenience.

Hereinafter, examples will be described in detail with reference to the accompanying drawings.

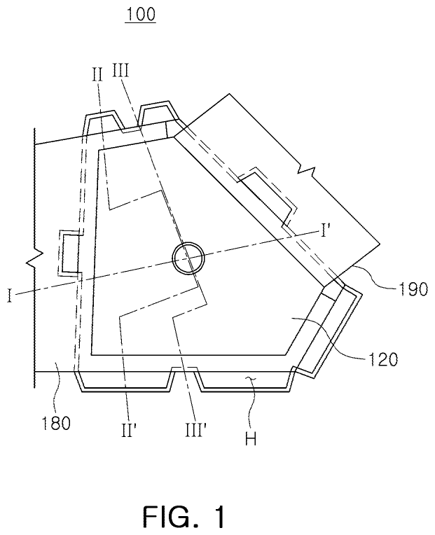

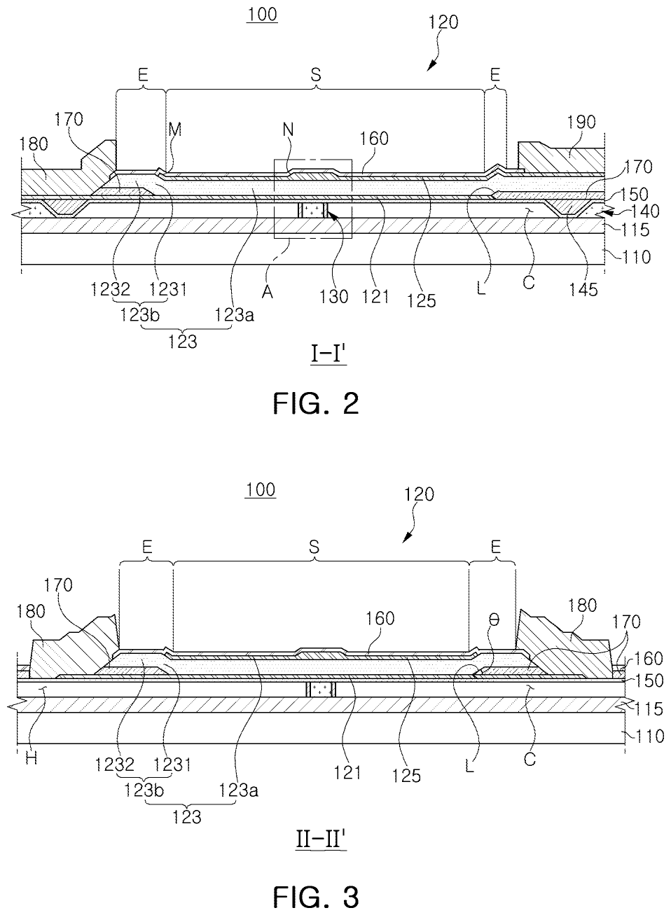

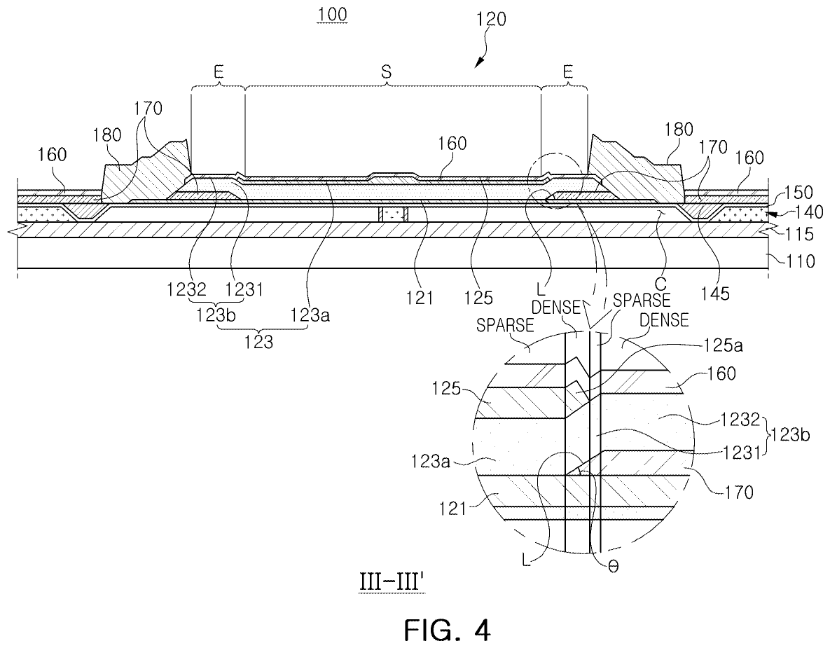

FIG. 1 is a plan view of a bulk acoustic wave resonator according to an example, FIG. 2 is a cross-sectional view taken along line I-I′ of FIG. 1, FIG. 3 is a cross-sectional view taken along line II-II′ of FIG. 1, and FIG. 4 is a cross-sectional view taken along line III-III′ of FIG. 1.

Referring to FIGS. 1 through 4, an acoustic resonator 100 may be a bulk acoustic wave (BAW) resonator, and may include a substrate 110, a support layer 140, a resonant portion 120, an insertion layer 170, and a heat dissipation portion 130.

The substrate 110 may be a silicon substrate. For example, a silicon wafer or a silicon on insulator (SOI) type substrate may be used as the substrate 110.

An insulating layer 115 may be provided on an upper surface of the substrate 110 to electrically isolate the substrate 110 and the resonant portion 120 from each other. In addition, the insulating layer 115 may prevent the substrate 110 from being etched by an etching gas at the time of forming a cavity C in a process of manufacturing the acoustic resonator.

In this case, the insulating layer 115 may be formed of at least one of silicon dioxide (SiO₂), silicon nitride (Si₃N₄), aluminum oxide (Al₂O₃), and aluminum nitride (AlN), and may be formed by any one of a chemical vapor deposition process, a radio frequency (RF) magnetron sputtering process, and an evaporation process.

The support layer 140 may be formed on the insulating layer 115, and may be disposed around the cavity C and an etching preventing portion 145 so as to surround the cavity C and the etching preventing portion 145 inside the support layer 140.

The cavity C may be formed as an empty space and may be formed by removing a portion of a sacrificial layer formed in a process of preparing the support layer 140, and the support layer 140 may be formed as a remaining portion of the sacrificial layer.

The support layer 140 may be formed of a material such as polysilicon (Poly-Si) or polymer that may be easily etched. However, the material of the support layer 140 is not limited thereto.

Since the cavity C is formed in the support layer 140, the resonant portion 120 formed on the support layer 140 may be entirely flat.

The etching preventing portion 145 may be disposed along a boundary of the cavity C. The etching preventing portion 145 may be provided in order to prevent etching from being performed beyond a cavity region in a process of forming the cavity C.

A membrane layer 150 may be formed on the support layer 140, and may form an upper surface of the cavity C. Therefore, the membrane layer 150 may also be formed of a material that is not easily removed in the process of forming the cavity C.

For example, when a halide based etching gas such as fluorine (F) or chlorine (Cl) is used to remove a portion (for example, a cavity region) of the support layer 140, the membrane layer 150 may be formed of a material of which reactivity to the abovementioned etching gas is low. In this case, the membrane layer 150 may include at least one of a silicon dioxide (SiO₂) and a silicon nitride (Si₃N₄).

In addition, the membrane layer 150 may be a dielectric layer containing at least one of magnesium oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), and zinc oxide (ZnO) or be a metal layer containing at least one of aluminum (Al), nickel (Ni), chromium (Cr), platinum (Pt), gallium (Ga), and hafnium (Hf). However, the membrane layer 150 is not limited thereto.

The resonant portion 120 may include a first electrode 121, a piezoelectric layer 123, and a second electrode 125. The resonant portion 120 may include the first electrode 121, the piezoelectric layer 123, and the second electrode 125 sequentially stacked from a lower portion thereof. Therefore, in the resonant portion 120, the piezoelectric layer 123 may be disposed between the first electrode 121 and the second electrode 125.

Since the resonant portion 120 is formed on the membrane layer 150, the membrane layer 150, the first electrode 121, the piezoelectric layer 123, and the second electrode 125 may be sequentially stacked on the substrate 110 to form the resonant portion 120.

The resonant portion 120 may resonate the piezoelectric layer 123 according to signals applied to the first electrode 121 and the second electrode 125 to generate a resonant frequency and an anti-resonant frequency.

The resonant portion 120 may be divided into a central portion S in which the first electrode 121, the piezoelectric layer 123, and the second electrode 125 are approximately flatly stacked and an extension portion E in which the insertion layer 170 is interposed between the first electrode 121 and the piezoelectric layer 123.

The central portion S may be a region disposed at the center of the resonant portion 120, and the extension portion E may be a region disposed along a circumference of the central portion S. Therefore, the extension portion E, a region extending outwardly from the central portion S, refers to a region formed in a continuous ring shape along the circumference of the central portion S. Alternatively, the extension portion E may be formed in a discontinuous ring shape of which some regions are disconnected.

Therefore, as illustrated in FIG. 2, in a cross-section of the resonant portion 120 cut across the central portion S, the extension portions E may be disposed at both ends of the central portion S, respectively. In addition, the insertion layer 170 may be inserted into both of the extension portions E disposed at both ends of the central portion S.

The insertion layer 170 may have an inclined surface L so as to have a thickness that becomes larger as it becomes more distant from the central portion S.

In the extension portion E, the piezoelectric layer 123 and the second electrode 125 may be disposed on the insertion layer 170. Therefore, the piezoelectric layer 123 and the second electrode 125 positioned in the extension portion E may have inclined surfaces according to a shape of the insertion layer 170.

Meanwhile, in the present example, it may be defined that the extension portion E is included in the resonant portion 120, and thus, resonance may also be generated in the extension portion E. However, a position at which the resonance is generated is not limited thereto. That is, the resonance may not be generated in the extension portion E according to a structure of the extension portion E, and may be generated only in the central portion S.

Each of the first electrode 121 and the second electrode 125 may be formed of a conductor, for example, gold, molybdenum, ruthenium, iridium, aluminum, platinum, titanium, tungsten, palladium, tantalum, chromium, or nickel, or a metal including at least one thereof, but is not limited thereto.

In the resonant portion 120, the first electrode 121 may be formed to have an area greater than that of the second electrode 125, and a first metal layer 180 may be disposed along an outer side of the first electrode 121 on the first electrode 121. Therefore, the first metal layer 180 may be disposed to be spaced apart from the second electrode 125 by a predetermined distance, and may be disposed to surround the resonant portion 120.

The first electrode 121 may be disposed on the membrane layer 150, and may thus be entirely flat. On the other hand, the second electrode 125 may be disposed on the piezoelectric layer 123, and may thus have a bend formed to correspond to a shape of the piezoelectric layer 123.

The first electrode 121 may be used as any one of an input electrode inputting an electrical signal such as a radio frequency (RF) signal and an output electrode outputting an electric signal.

The second electrode 125 may be entirely disposed in the central portion S, and may be partially disposed in the extension portion E. Therefore, the second electrode 125 may be divided into a portion disposed on a piezoelectric portion 123a of the piezoelectric layer 123 to be described later and a portion disposed on a bent portion 123b of the piezoelectric layer 123.

More specifically, in the present example, the second electrode 125 may be disposed to cover the entirety of the piezoelectric portion 123a and a portion of an inclined portion 1231 of the piezoelectric layer 123. Therefore, a second electrode portion 125a (see FIG. 4) disposed in the extension portion E may have an area smaller than that of an inclined surface of the inclined portion 1231, and the second electrode 125 may have an area smaller than that of the piezoelectric layer 123 in the resonant portion 120.

Therefore, as illustrated in FIG. 2, in the cross-section of the resonant portion 120 cut across the central portion S, a distal end of the second electrode 125 may be disposed in the extension portion E. In addition, at least a portion of the distal end of the second electrode 125 disposed in the extension portion E may be disposed to overlap the insertion layer 170. Here, the term “overlap” means that when the second electrode 125 is projected on a plane on which the insertion layer 170 is disposed, a shape of the second electrode 125 projected on the plane overlaps the insertion layer 170. In this case, the distal end of the second electrode 125 may be disposed on the inclined portion 1231 of the piezoelectric layer 123.

The second electrode 125 may be used as any one of an input electrode inputting an electrical signal such as a radio frequency (RF) signal and an output electrode outputting an electric signal. That is, when the first electrode 121 is used as the input electrode, the second electrode 125 may be used as the output electrode, and when the first electrode 121 is used as the output electrode, the second electrode 125 may be used as the input electrode.

As illustrated in FIG. 4, when the distal end of the second electrode 125 is positioned on the inclined portion 1231 of the piezoelectric layer 123, acoustic impedance of the resonant portion 120 may have a local structure formed in a sparse/dense/sparse/dense structure from the central portion S, and a reflection interface reflecting lateral waves inwardly of the resonant portion 120 may thus be increased. Therefore, most of the lateral waves may not escape outwardly of the resonant portion 120 and may be reflected inwardly of the resonant portion 120, and performance of the acoustic resonator may thus be improved.

The piezoelectric layer 123 may be a portion generating a piezoelectric effect of converting electrical energy into mechanical energy having an elastic wave form, and may be formed on the first electrode 121 and an insertion layer 170 to be described later.

Zinc oxide (ZnO), aluminum nitride (AlN), doped aluminum nitride, lead zirconate titanate, quartz, or the like, may be selectively used as a material of the piezoelectric layer 123. The doped aluminum nitride may further include a rare earth metal, a transition metal, or an alkaline earth metal. The rare earth metal may include at least one of scandium (Sc), erbium (Er), yttrium (Y), and lanthanum (La). The transition metal may include at least one of hafnium (Hf), titanium (Ti), zirconium (Zr), tantalum (Ta), and niobium (Nb). In addition, the alkaline earth metal may include magnesium (Mg).

When a content of elements doped in aluminum nitride (AlN) in order to improve piezoelectric characteristics is less than 0.1 at %, piezoelectric characteristics higher than those of aluminum nitride (AlN) may not be implemented, and when a content of elements doped in aluminum nitride (AlN) exceeds 30 at %, it is difficult to perform manufacture and composition control for deposition, such that a non-uniform phase may be formed.

Therefore, the content of elements doped in aluminum nitride (AlN) may be in the range of 0.1 to 30 at %.

In the present example, aluminum nitride (AlN) doped with scandium (Sc) may be used as the material of the piezoelectric layer. In this case, a piezoelectric constant may be increased to increase Kₜ² of the acoustic resonator.

The piezoelectric layer 123 may include the piezoelectric portion 123a disposed in the central portion S and the bent portion 123b disposed in the extension portion E.

The piezoelectric portion 123a may be a portion directly stacked on an upper surface of the first electrode 121. Therefore, the piezoelectric portion 123a may be interposed between the first electrode 121 and the second electrode 125 and be formed to be flat together with the first electrode 121 and the second electrode 125.

The bent portion 123b may refer to a region extending outwardly from the piezoelectric portion 123a and positioned in the extension portion E.

The bent portion 123b may be disposed on the insertion layer 170, and may have an upper surface raised according to a shape of the insertion layer 170. Therefore, the piezoelectric layer 123 may be bent at a boundary between the piezoelectric portion 123a and the bent portion 123b, and the bent portion 123b may be raised according to a thickness and a shape of the insertion layer 170.

The bent portion 123b may be divided into the inclined portion 1231 and an extending portion 1232.

The inclined portion 1231 may refer to a portion inclined along an inclined surface L of the insertion layer 170. In addition, the extending portion 1232 may refer to a portion extending outwardly from the inclined portion 1231.

The inclined portion 1231 may be formed in parallel with the inclined surface L of the insertion layer 170, and an inclination angle of the inclined portion 1231 may be the same as an inclination angle of the inclined surface L of the insertion layer 170.

The insertion layer 170 may be disposed along a surface formed by the membrane layer 150, the first electrode 121, and the etching preventing portion 145. Therefore, the insertion layer 170 may be partially disposed in the resonant portion 120, and may be disposed between the first electrode 121 and the piezoelectric layer 123.

The insertion layer 170 may be disposed around the central portion S and support the bent portion 123b of the piezoelectric layer 123. Therefore, the bent portion 123b of the piezoelectric layer 123 may be divided into the inclined portion 1231 and the extending portion 1232 according to the shape of the insertion layer 170.

In the present example, the insertion layer 170 may be disposed in a region except for the central portion S. For example, the insertion layer 170 may be disposed over the entirety of the region except for the central portion S or be disposed in a portion of the region except for the central portion S on the substrate 110.

The insertion layer 170 may have a thickness that becomes larger as it becomes more distant from the central portion S. Therefore, a side surface of the insertion layer 170 disposed adjacently to the central portion S may be formed as the inclined surface L having a predetermined inclination angle θ.

When the inclination angle θ of the side surface of the insertion layer 170 is smaller than 5°, a thickness of the insertion layer 170 needs to be very small or an area of the inclined surface L needs to be excessively large in order to manufacture the insertion layer 170 of which the inclination angle θ of the side surface is smaller than 5°, substantially difficult to be implemented.

In addition, when the inclination angle θ of the side surface of the insertion layer 170 is greater than 70°, an inclination angle of the piezoelectric layer 123 or the second electrode 125 stacked on the insertion layer 170 may be greater than 70°. In this case, the piezoelectric layer 123 or the second electrode 125 stacked on the inclined surface L may be excessively bent, and a crack may thus occur in a bent portion.

Therefore, in the present example, the inclination angle θ of the inclined surface L may be in a range of 5° or more to 70° or less.

In the present example, the inclined portion 1231 of the piezoelectric layer 123 may be formed along the inclined surface L of the insertion layer 170, and may thus be formed at the same inclination angle as the inclined surface L of the insertion layer 170. Therefore, the inclination angle of the inclined portion 1231 may also be in a range of 5° or more to 70° or less, similar to the inclined surface L of the insertion layer 170. Such a configuration may also be similarly applied to the second electrode 125 stacked on the inclined surface L of the insertion layer 170.

The insertion layer 170 may be formed of a dielectric material such as silicon dioxide (SiO₂), aluminum nitride (AlN), aluminum oxide (Al₂O₃), silicon nitride (Si₃N₄), magnesium oxide (MgO), zirconium oxide (ZrO₂), lead zirconate titanate (PZT), gallium arsenide (GaAs), hafnium oxide (HfO₂), titanium oxide (TiO₂), or zinc oxide (ZnO), but may be formed of a material different from that of the piezoelectric layer 123.

Alternatively, the insertion layer 170 may be formed of a metal. When the bulk acoustic wave resonator is used for 5G communications, a large amount of heat may be generated in the resonant portion, and thus, the heat generated in the resonant portion 120 needs to be smoothly dissipated. To this end, the insertion layer 170 may be formed of an aluminum alloy material containing scandium (Sc).

The resonant portion 120 may be disposed to be spaced apart from the substrate 110 through the cavity C formed as the empty space. A portion of the resonant portion 120 may be fixed to the substrate 110 by a heat dissipation portion 130.

The cavity C may be formed by supplying an etching gas (or an etchant) to introduction holes H (see FIG. 1) in the process of manufacturing the acoustic resonator to remove a portion of the support layer 140.

A protective layer 160 may be disposed along a surface of the acoustic resonator 100 to prevent the acoustic resonator 100 from external impact. The protective layer 160 may be disposed along a surface formed by the second electrode 125 and the bent portion 123b of the piezoelectric layer 123.

In the present example, the protective layer 160 may be formed of various materials as long as it may protect a surface of the second electrode 125. For example, the protective layer 160 may be formed of any one of a silicon oxide-based insulating material, a silicon nitride-based insulating material, an aluminum oxide-based insulating material, and an aluminum nitride-based insulating material. In addition, the protective layer 160 may be formed of a diamond material having an excellent thermal conductivity.

The protective layer 160 configured as described above may be formed of one layer, but may also be formed by stacking two layers of which materials are different from each other, if necessary. In addition, the protective layer 160 may be partially removed in order to control a frequency in a final process. For example, a thickness of the protective layer 160 may be controlled in a manufacturing process.

The first electrode 121 and the second electrode 125 may extend outward of the resonant portion 120. In addition, the first metal layer 180 and a second metal layer 190 may be disposed on upper surfaces of the extending portions, respectively.

Each of the first metal layer 180 and the second metal layer 190 may be formed of any one of gold (Au), a gold-tin (Au—Sn) alloy, copper (Cu), a copper-tin (Cu—Sn) alloy, aluminum (Al), and an aluminum alloy. Here, the aluminum alloy may be an aluminum-germanium (Al—Ge) alloy or an aluminum-scandium (Al—Sc) alloy.

The first metal layer 180 and the second metal layer 190 may function as connection wirings electrically connecting the first and second electrodes 121 and 125 of the bulk acoustic wave resonator according to the present example to electrodes of another bulk acoustic wave resonator disposed adjacent to the bulk acoustic wave resonator according to the present example on the substrate 110.

The first metal layer 180 may be bonded to the first electrode 121.

In addition, in the resonant portion 120, the first electrode 121 may be formed to have an area greater than that of the second electrode 125, and the first metal layer 180 may be formed at a circumferential portion of the first electrode 121.

Therefore, the first metal layer 180 may be disposed along a circumference of the resonant portion 120, and may thus be disposed to surround the second electrode 125. However, the first metal layer 180 is not limited to such a configuration.

Heat may be generated in the resonant portion 120 by an electric field and vibrations applied to the resonant portion 120. Since the cavity C is provided between the resonant portion 120 and the substrate 110, the heat generated in the resonant portion 120 may not be transferred directly to the substrate 110 due to the cavity C, and may be mostly transferred in a horizontal direction. The heat transferred in the horizontal direction may be transferred to the substrate 110 through the support layer 140 and/or the etching preventing portion 145.

The bulk acoustic wave resonator according to the present example may provide an additional dissipation path of the heat generated in the resonant portion 120 by including the heat dissipation portion 130. Therefore, the bulk acoustic wave resonator 100 according to the present example may have further improved robustness by improving heat generation efficiency while having an improved quality factor according to the cavity C.

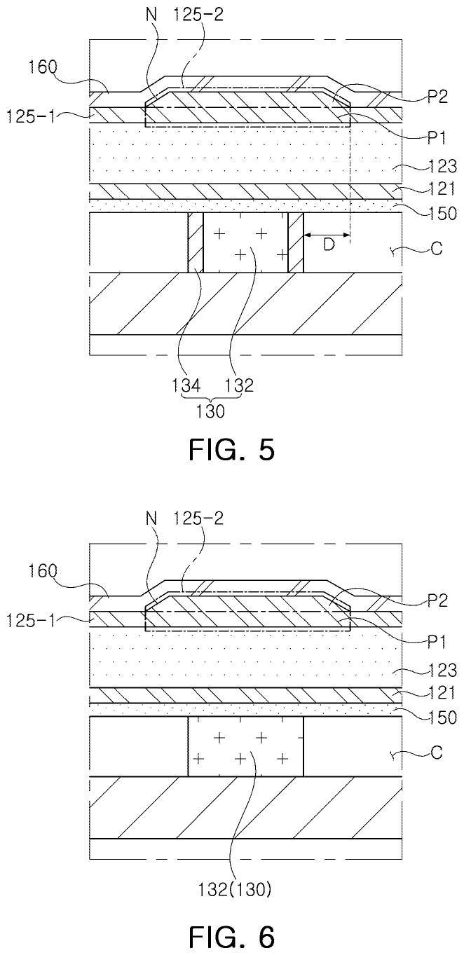

FIGS. 5 and 6 are enlarged views of part A of FIG. 2, and FIG. 6 illustrates a modified example of a heat dissipation portion illustrated in FIG. 5.

First, referring to FIG. 5, the heat dissipation portion 130 may be positioned in the cavity C, and may be disposed between the resonant portion 120 and the substrate 110 to support a portion of the resonant portion 120. In order to efficiently dissipate the heat, the heat dissipation portion 130 may be disposed at a central portion of the resonant portion 120, a position farthest from the etching preventing portion 145.

The heat dissipation portion 130 may include a heat conduction portion 132 disposed in a pillar shape between the resonant portion 120 and the substrate 110 and an etch-stop layer 134 surrounding a side surface of the heat conduction portion 132.

The heat conduction portion 132 may be formed in a pillar shape of which one end is bonded to the resonant portion 120 and the other end is bonded to the substrate 110. The heat conduction portion 132 may be formed of the same material as that of the support layer 140, but is not limited thereto. For example, the heat conduction portion 132 may be formed of a material having thermal conductivity higher than that of the etch-stop layer 134. In this case, the heat generated in the resonant portion 120 may be more efficiently transferred to the substrate 110.

For example, when the support layer 140 is formed of poly silicon (poly-Si), the etch-stop layer 134 may be formed of a material having high thermal conductivity, such as an aluminum nitride (AlN)-based material and aluminum nitride (AlN) doped with a rare earth metal.

The etch-stop layer 134 may be provided in order to prevent the heat conduction portion 132 from being removed together with the sacrificial layer in the process of forming the cavity C. Therefore, the etch-stop layer 134 may be disposed on the surface of the heat conduction portion 132 so as to surround the side surface of the heat conduction portion 132.

The etch-stop layer 134 may be formed of the same material as that of the etching preventing portion 145, but is not limited thereto.

Meanwhile, as illustrated in FIG. 6, the heat dissipation portion 130 according to an example may include only the heat conduction portion 132 without including the etch-stop layer. In this case, the heat conduction portion 132 may be formed of a metal having high thermal conductivity. For example, the heat conduction portion 132 may be formed of gold (Au) or copper (Cu). Therefore, the heat generated in the resonant portion 120 may be more efficiently transferred to the substrate 110.

The resonant portion 120 may include the first electrode 121, the piezoelectric layer 123, and the second electrode 125 sequentially stacked on the heat dissipation portion 130. In addition, referring to FIG. 5, the second electrode 125 may include a first region 125-1 and a second region 125-2 divided according to a thickness thereof.

The second region 125-2, a region disposed above the heat dissipation portion 130, may be formed to have a thickness greater than that of the first region 125-1. Therefore, the first region 125-1 may be defined as a region having a uniform thickness as a whole and having a thickness smaller than that of the second region 125-2.

A boundary between the first region 125-1 and the second region 125-2 formed due to a thickness difference between the first region 125-1 and the second region 125-2 may be formed as an inclined surface N (see FIG. 5). However, the boundary between the first region 125-1 and the second region 125-2 is not limited thereto, and may be variously modified.

The inclined surface N may be formed in a shape in which a thickness of the second electrode 125 decreases toward the first region 125-1.

The second region 125-2 may be positioned in the first region 125-1. Therefore, the first region 125-1 may be disposed around the second region 125-2.

The second region 125-2 may be partially disposed in a region corresponding to the heat dissipation portion 130 in an entire region of the second electrode 125, and may be formed to have an area greater than that of a bonded surface (for example, a bonded surface between the heat dissipation portion and the membrane layer) of the heat dissipation portion 130 bonded to the resonant portion 120. Therefore, the heat dissipation portion 130 may be disposed so that the entirety of the bonded surface faces the second region 125-2. Here, a phrase “entirety of the bonded surface faces the second region” means that when the bonded surface of the heat dissipation portion 130 is projected onto the second electrode 125, the entirety of the bonded surface of the heat dissipation portion 130 is disposed to overlap the second region 125-2.

In the present example, the second region 125-2 may be formed of the same material as that of the first region 125-1. Therefore, the first region 125-1 and the second region 125-2 may be formed together in a process of manufacturing the second electrode 125. For example, the second electrode 125 may be formed by forming a thin film at a thickness of the second region 125-2 and then decreasing a thickness of the first region 125-1 by a method such as etching.

However, the second electrode 125 is not limited to such a configuration. For example, various methods of forming a thin film layer at a thickness of the first region 125-1 and then increasing a portion of the first region 125-1 by a method such as plating, deposition, or sputtering to additionally form the second region 125-2 may be used.

In the present example, the second region 125-2 may be divided into an electrode layer P1 formed at the same thickness as that of the first region 125-1 and a thickened layer P2 formed on the electrode layer P1. Therefore, the first region 125-1 may be entirely formed of the electrode layer P1, and the second region 125-2 may be divided into a region in which the thickened layer P2 is formed on the electrode layer P1.

The electrode layer P1 and the thickened layer P2 may be formed of the same material. However, the electrode layer P1 and the thickened layer P2 are not limited thereto, and may also be formed of different materials. In this case, in order to significantly decrease electrical resistance in the second electrode 125, the thickened layer P2 may be formed of a material having an electrical conductivity similar to that of the electrode layer P1.

As described above, a side surface of the thickened layer P2 disposed along the boundary between the first region 125-1 and the second region 125-2 may be formed as the inclined surface N. In addition, the thickened layer P2 may be formed in a shape in which an area (for example, a horizontal cross-sectional area) of the thickened layer P2 increases toward the electrode layer P1. Therefore, the thickened layer P2 according to the present example may be formed to have a greater area in a lower surface thereof than in an upper surface thereof.

Therefore, a horizontal area of the thickened layer P2 may be greater than the area of the bonded surface of the heat dissipation portion 130, and the entirety of the boundary between the first region 125-1 and the second region 125-2 is not disposed above the heat dissipation portion 130, and may be disposed above the cavity C.

The inclined surface N of the thickened layer P2 may be disposed to face an inclined surface M (see FIG. 2) of the second electrode portion 125a disposed on the inclined portion 1231. In addition, the inclined surface N of the thickened layer P2 may be formed to have an inclination angle that is the same as or similar to that of the inclined surface M of the second electrode 125 disposed on the inclined portion 1231. However, the inclined surface N of the thickened layer P2 is not limited to such a configuration.

The inclined surface N of the thickened layer P2, the boundary between the first region 125-1 and the second layer 125-2, may be disposed in a position spaced apart from a side surface of the heat dissipation portion 130 by a predetermined distance D (see FIG. 5) in a surface direction of the resonant portion 120.

In addition, a portion of the thickened layer P2 disposed outside the heat dissipation portion 130, in other words, a portion of the thickened layer P2 that does not face the bonded surface of the heat dissipation portion 130 may function as a frame reflecting lateral waves propagated to the heat dissipation portion 130 within the resonant portion 120.

Therefore, a region of the thickened layer P2 included in range D of FIG. 5 in a cross section of the resonant portion 120 cut across the heat dissipation portion 130 as illustrated in FIG. 5 may function as the frame. To this end, a width of a portion in range D of the thickened layer P2 disposed outside the heat dissipation portion 130 may be λ/4 or an integer multiple of λ/4 in which λ is a wavelength of the abovementioned lateral wave.

Through such a configuration, in the bulk acoustic wave resonator according to the present example, a phenomenon in which vibrational energy of the resonant portion 120 is leaked outwardly of the resonant portion 120 through the heat dissipation portion 130 may be suppressed.

In the bulk acoustic wave resonator 100 described above, the heat of the resonant portion 120 may be dissipated to the substrate 110 through the heat dissipation portion 130, and heat dissipation performance may thus be improved. Therefore, even though high power is applied to the resonant portion 120, operation reliability of the bulk acoustic wave resonator 100 may be secured, such that the bulk acoustic wave resonator 100 may be utilized as a bulk acoustic wave resonator suitable for 5G communications.

In addition, the vibrational energy of the resonant portion 120 propagated to the heat dissipation portion 130 may be reflected through the thickened layer P2, and efficiency of the bulk acoustic wave resonator may thus be improved.

Meanwhile, when the second electrode 125 is omitted above the heat dissipation portion 130, electrical resistance of the second electrode 125 above the heat dissipation portion 130 may be increased. On the other hand, in the bulk acoustic wave resonator 100, the thickness of the second electrode 125 above the heat dissipation portion 130 may be increased, and an increase in the electrical resistance of the second electrode 125 above the heat dissipation portion 130 may thus be suppressed.

Therefore, in the bulk acoustic wave resonator 100, basic performance (for example, a quality factor (QF) or an electromechanical coupling coefficient (Kₜ²)) of the bulk acoustic wave resonator may be improved by significantly decreasing leakage and loss of energy while securing heat dissipation performance.

Meanwhile, the examples are not limited to the abovementioned configurations, and may be variously modified.

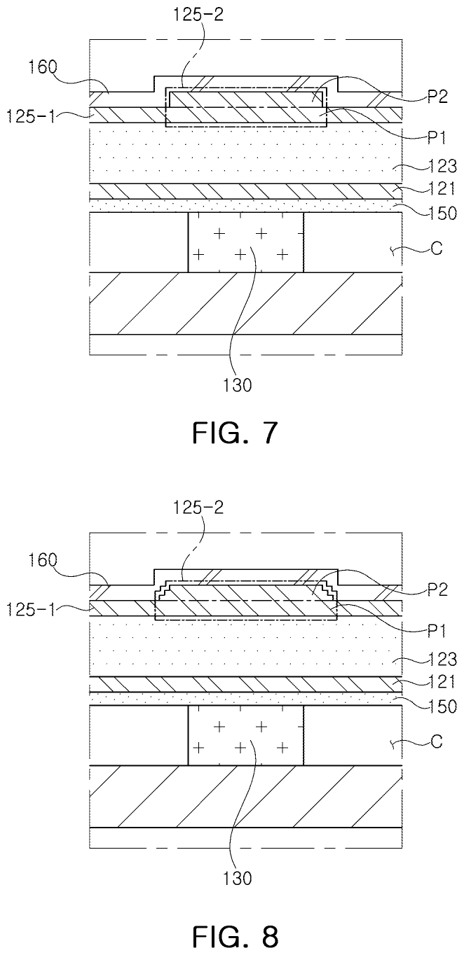

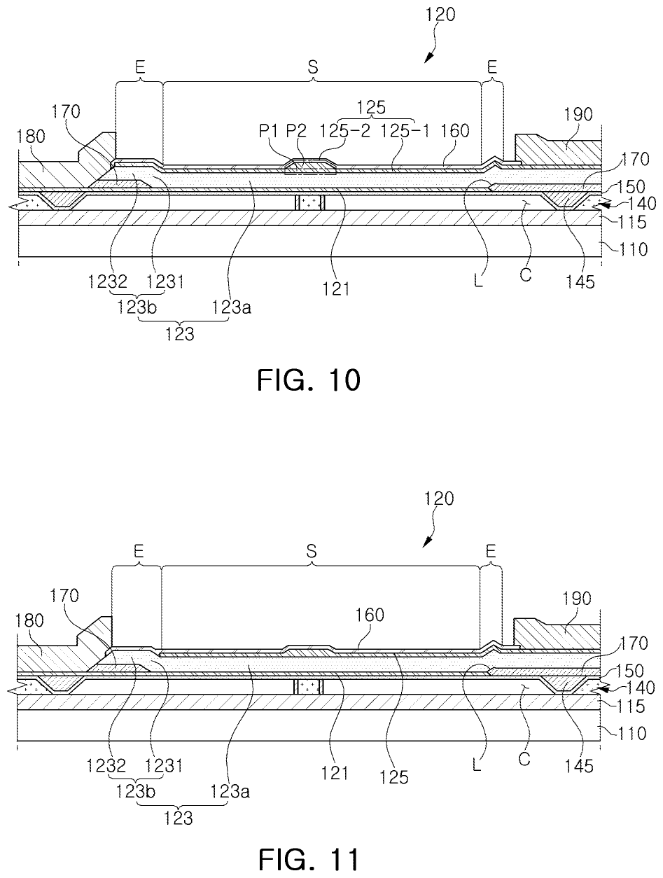

FIGS. 7 through 11 are schematic cross-sectional views illustrating bulk acoustic wave resonators according to other examples, wherein FIGS. 7 through 9 illustrate cross sections corresponding to FIG. 5, and FIGS. 10 and 11 illustrate cross sections corresponding to FIG. 2.

First, referring to FIG. 7, in a bulk acoustic wave resonator, a side surface of the thickened layer P2 forming the boundary between the first region 125-1 and the second region 125-2 may be formed as a vertical surface rather than the inclined surface. In this case, the thickened layer P2 may be formed to have the same area in an upper surface and a lower surface thereof.

In addition, referring to FIG. 8, in a bulk acoustic wave resonator, a side surface of the thickened layer P2 forming the boundary between the first region 125-1 and the second region 125-2 may be formed in a step shape. In addition, although not illustrated, the side surface of the thickened layer P2 may also be formed as a convex or concave curved surface.

As described above, in the bulk acoustic wave resonator according to the various examples, the side surface of the thickened layer P2 may be modified in various forms.

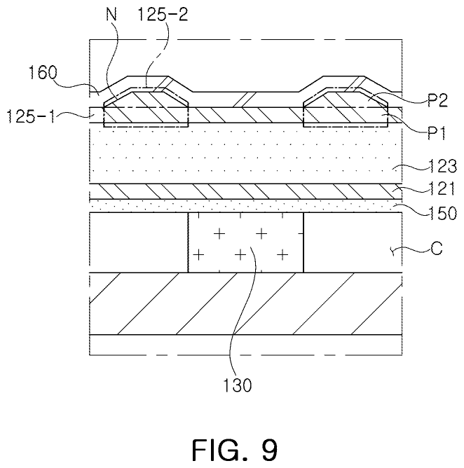

Referring to FIG. 9, in a bulk acoustic wave resonator, the thickened layer P2 is not disposed above the heat dissipation portion 130, and may be disposed only around the heat dissipation portion 130. Therefore, the thickened layer P2 may be disposed on the electrode layer P1 in an annular ring shape along a contour of the heat dissipation portion 130.

In the present example, the entirety of the thickened layer P2 may be disposed outside the heat dissipation portion 130. Therefore, the thickened layer P2 may be disposed so that the entirety thereof does not face the bonded surface of the heat dissipation portion 130.

However, the configuration of the thickened layer P2 is not limited thereto, and may be variously modified. For example, the thickened layer P2 may be configured so that at least a portion thereof is positioned above the heat dissipation portion 130.

Referring to FIG. 10, in a bulk acoustic wave resonator, the second electrode 125 may be disposed over the entirety of an upper surface of the piezoelectric layer 123 within the resonant portion 120. Therefore, the second electrode 125 may be formed on the extending portion 1232 of the piezoelectric layer 123 as well as on the inclined portion 1231 of the piezoelectric layer 123.

In this case, in a position where the insertion layer 170 is disposed, a thickness of the resonant portion 120 may be increased by a thickness of the second electrode 125 as compared to the abovementioned example. In the bulk acoustic wave resonator according to the present example, a thickness of the thickened layer P2 may be the same as or similar to that of the insertion layer 170, and an entire thickness of the second region 125-2 may thus be greater than that of the insertion layer 170.

Referring to FIG. 11, in a bulk acoustic wave resonator, in a cross section of the resonant portion 120 cut across the central portion S, a distal end of the second electrode 125 may be formed only on an upper surface of the piezoelectric portion 123a of the piezoelectric layer 123, and may not be formed on the bent portion 123b of the piezoelectric layer 123. Therefore, the distal end of the second electrode 125 may be disposed along a boundary between the piezoelectric portion 123a and the inclined portion 1231.

As described above, the bulk acoustic wave resonator according to the various examples may be modified in various forms, if necessary.

As set forth above, in the bulk acoustic wave resonator according to the various examples, efficiency of the bulk acoustic wave resonator may be improved by significantly decreasing leakage and loss of energy while securing heat dissipation performance.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed to have a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk acoustic wave resonator comprising:
a substrate;
a resonant portion comprising a sequentially stacked first electrode, piezoelectric layer, and second electrode;
a cavity defined between the substrate and the resonant portion; and
a heat dissipation portion disposed in the cavity and supporting the resonant portion,
wherein the second electrode includes a first region and a second region having a thickness greater than a thickness of the first region, and
the second region of the second electrode is disposed above the heat dissipation portion.

2. The bulk acoustic wave resonator of claim 1, wherein the second electrode comprises an inclined surface at a boundary between the first region and the second region.

3. The bulk acoustic wave resonator of claim 1, wherein the heat dissipation portion is bonded to the resonant portion and the second region of the second electrode has an area greater than an area of a bonded surface of the heat dissipation portion bonded to the resonant portion, and
the heat dissipation portion is disposed so that an entirety of the bonded surface faces the second region of the second electrode.

4. The bulk acoustic wave resonator of claim 1, wherein the heat dissipation portion comprises a heat conduction portion having a pillar shape in which one end is bonded to the resonant portion and the other end is bonded to the substrate.

5. The bulk acoustic wave resonator of claim 4, wherein the heat dissipation portion comprises an etch-stop layer surrounding a side surface of the heat conduction portion.

6. The bulk acoustic wave resonator of claim 5, wherein the heat conduction portion comprises a material having thermal conductivity higher than a thermal conductivity of the etch-stop layer.

7. The bulk acoustic wave resonator of claim 3, wherein a boundary between the first region of the second electrode and the second region of the second electrode is spaced apart from a side surface of the heat dissipation portion by a predetermined distance in a surface direction of the resonant portion.

8. The bulk acoustic wave resonator of claim 7, wherein a horizontal distance from the side surface of the heat dissipation portion to the boundary between the first region of the second electrode and the second region of the second electrode is λ/4 or an integer multiple of λ/4 in which λ is a wavelength of a lateral wave propagated from the resonant portion to the heat dissipation portion.

9. The bulk acoustic wave resonator of claim 1, wherein the second electrode comprises a vertical surface or a stepped surface at a boundary between the first region and the second region.

10. The bulk acoustic wave resonator of claim 1, wherein the second region of the second electrode has an annular ring shape along a contour of the heat dissipation portion.

11. The bulk acoustic wave resonator of claim 1, further comprising an insertion layer disposed between the first electrode and the piezoelectric layer,
wherein at least a portion of the piezoelectric layer is raised by the insertion layer.

12. The bulk acoustic wave resonator of claim 11, wherein the insertion layer comprises an inclined surface,
the piezoelectric layer comprises a piezoelectric portion disposed on the first electrode and an inclined portion disposed on the inclined surface of the insertion layer, and
in a cross section of the resonant portion, a distal end of the second electrode is disposed on the inclined portion of the piezoelectric layer.

13. The bulk acoustic wave resonator of claim 12, wherein the piezoelectric layer comprises an extending portion disposed outside the inclined portion, and
at least a portion of the second electrode is disposed on the extending portion of the piezoelectric layer.

14. The bulk acoustic wave resonator of claim 13, wherein the second region of the second electrode has a thickness greater than a thickness of the insertion layer.

15. A bulk acoustic wave resonator comprising:
a substrate;
a resonant portion comprising a sequentially stacked first electrode, piezoelectric layer, and second electrode;
a cavity defined between the substrate and the resonant portion; and
a heat dissipation portion disposed in the cavity and supporting the resonant portion,
wherein the second electrode comprises an electrode layer stacked on the piezoelectric layer and a thickened layer partially formed on a region of the electrode layer corresponding to the heat dissipation portion to increase a thickness of the second electrode, and
the thickened layer has an area greater than an area of a bonded surface of the heat dissipation portion bonded to the resonant portion.

16. The bulk acoustic wave resonator of claim 15, wherein an entirety of a side surface of the thickened layer is disposed above the cavity.

17. A bulk acoustic wave resonator comprising:
a substrate;
a resonant portion comprising a first electrode, a piezoelectric layer disposed on the first electrode, and a second electrode disposed on the piezoelectric layer and comprising a thickened portion;
a cavity defined between the substrate and the resonant portion; and
a heat dissipation pillar disposed in the cavity and bonded to the resonant portion such that at least a portion of the thickened portion of the second electrode overlaps the heat dissipation pillar in a thickness direction of the bulk acoustic wave resonator.

18. The bulk acoustic wave resonator of claim 17, wherein the thickened portion of the second electrode has a length along a direction normal to the thickness direction of the bulk acoustic wave resonator that is greater than a length of a surface of the heat dissipation pillar that is bonded to the resonant portion along the direction normal to the thickness direction of the bulk acoustic wave resonator.
